(19) United States
(12) Patent Application Publication
(10) Pub. No.: US 2002/0102813 A1
(43) Pub. Date: Aug. 1, 2002

(54) Method for manufacturing semiconductor device on silicon-on-insulator substrate

(76) Inventors: Der-Yuan Wu, Hsin-Chu City (TW); Chih-Cheng Liu, Taipei (TW)

Correspondence Address: POWELL, GOLDSTEIN, FRAZER & MURPHY LLP, P.O. BOX 97233, WASHINGTON, DC, 20090-7233, US

(21) Appl. No.: 09/774,774

(22) Filed: Jan. 31, 2001

(51) Int. Cl. H01L 21/76

(52) U.S. Cl. 438/404; 438/405; 438/412

(57) ABSTRACT

A method for manufacturing a semiconductor device with a shallow channel on a silicon-on-insulator substrate is disclosed. The method uses a dielectric layer as a mask, an oxygen implantation and a heating process to form a silicon dioxide layer within a silicon-on-insulator substrate before forming a gate electrode on the silicon-on-insulator substrate. That is, the junction depth of the channel is reduced. First of all, a silicon-on-insulator substrate having a silicon layer and an insulating layer is provided, wherein the silicon layer is separated by the insulating layer. Secondly, a first dielectric layer is deposited on the silicon layer. Thirdly, a gate region pattern is transferred into the first dielectric layer to form a trench and expose the silicon layer. Then, oxygen molecules are implanted into the silicon layer, and the silicon-on-insulator substrate is heated to form a silicon dioxide layer therein. Next, a second dielectric layer is deposited and the trench is filled with the same. Then, two spacers are formed in the trench by anisotropically etching the second dielectric layer. Furthermore, a gate electrode is formed by filling the trench with a conductive layer. Moreover, the first dielectric layer is removed. Finally, source and drain regions are formed in the silicon layer.

### BACKGROUND OF THE INVENTION

1. Field of the Invention

The present invention relates to a method for manufacturing a semiconductor device on a silicon-on-insulator (SOI) substrate and more particularly to a method for manufacturing a semiconductor device with a shallow channel on a SOI substrate.

2. Description of the Related Art

Silicon-on-insulator (SOI) structure is a technique for isolating a semiconductor device by using an insulating layer. The semiconductor device can be, for example, a metal oxide semiconductor (MOS) field effect transistor (FET). The SOI structure can be fabricated by using implanted oxygen (SIMOX) method, bonded wafer method and dielectric isolation (DI) method. The principle is to establish a layer of insulating material, for example, a silicon dioxide layer, close to a surface of a silicon layer, thereby provides electrical isolation. That is, the SOI structure provides a MOSFET fabricated therein and thereon with improved device isolation, reduced junction capacitance, and prevents the leakage current of the source/drain region from being formed.

FIG. 1 is a cross sectional view showing an N-type MOSFET on a SOI substrate. The SOI substrate comprised a P-type silicon layer 100, a silicon dioxide layer 102 and a silicon layer 104 is shown, wherein the silicon layer 100 has two spacers 114a, 114b, a gate electrode 116 thereon, and source and drain regions 118a, 118b therein. This MOSFET on the SOI substrate has all the advantages mentioned above, however, as the integration of the integrated circuit device continuously increases, the line width of the gate electrode 116 must decrease. Moreover, in order to operate the MOSFET in high speed with reliable performance, the resistance of the source and drain regions 118a, 118b must be reduced as possible, and therefore the RC time delay value can be degraded. Furthermore, due to the heat dissipation problem resulted from the high speed operation, the voltage used to control the gate electrode 116 is necessary low, whereas, as the result of reducing the voltage, the performance of the channel control of the gate electrode 116 also degrades. One strategy of solving this problem is to reduce the junction depth of the channel, the source and drain regions 118a, 118b together. But it also causes the increase of the resistance of the source and drain regions 118a, 118b, and the raise of the RC time delay value. Thus it is necessary to provide a method for increasing the ability of channel control with low voltage of gate control, meanwhile, maintaining lower resistance of source and drain regions, and less RC time delay value. It is towards those goals that the present invention is specifically directed.

### SUMMARY OF THE INVENTION

It is therefore an object of the invention to increase the ability of channel control of the gate electrode by reducing the junction depth of the channel.

It is another object of this invention to increase the ability of channel control of the gate electrode, meanwhile, maintaining the junction depth of the source and drain regions, and lower resistance of the same.

It is a further object of this invention to increase the ability of channel control of the gate electrode without increasing the RC time delay value.

It is another object of this invention that the gate voltage of the SOI device of this invention can be decreased without degrading the performance of channel control.

To achieve these objects, and in accordance with the purpose of the invention, the invention use a dielectric layer as a mask, an oxygen implantation and a heating process to form a silicon dioxide layer within a silicon-on-insulator substrate before forming a gate electrode on the silicon-on-insulator substrate. That is, the depth of the channel is reduced. Firstly, a silicon-on-insulator substrate having a silicon layer and an insulating layer is provided, wherein the silicon layer is separated by the insulating layer. Secondly, a first dielectric layer is deposited on the silicon layer. Thirdly, a gate region pattern is transferred into the first dielectric layer to form a trench and expose the silicon layer. Then, oxygen molecules are implanted into the silicon layer, and the silicon-on-insulator substrate is heated to form a silicon dioxide layer in the silicon layer. Next, a second dielectric layer is deposited and the trench is filled with the same. Then, two spacers are formed in the trench by anisotropically etching the second dielectric layer. Furthermore, a gate electrode is formed by filling the trench with a conductive layer. Moreover, the first dielectric layer is removed. Finally, source and drain regions are formed in the silicon layer.

It is to be understood that both the foregoing general description and the following detailed description are exemplary and explanatory only and are not restrictive of the invention, as claimed.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is schematic cross sectional diagrams of a conventional metal oxide semiconductor field effect transistor on a SOI substrate;

FIG. 2 shows a result of depositing a first dielectric layer on a SOI substrate;

FIG. 3 shows a result of transferring a gate region pattern into the first dielectric layer shown in FIG. 2 to form a trench and expose the SOI substrate;

FIG. 4 shows an implantation process of oxygen performed on the SOI substrate shown in FIG. 3;

FIG. 5 shows a result of heating the SOI substrate shown in FIG. 4 to form a silicon dioxide layer therein;

FIG. 6 shows a result of depositing a second dielectric layer on the SOI substrate shown in FIG. 5;

FIG. 7 shows a result a result of anisotropically etching the second dielectric layer to form two spacers in the trench;

FIG. 8 shows a result of filling the trench shown in FIG. 9 with a conductive layer; and

FIG. 9 shows a result of removing the first dielectric layer and an ion implantation process sequentially performed on the SOI substrate to form source and drain regions therein.

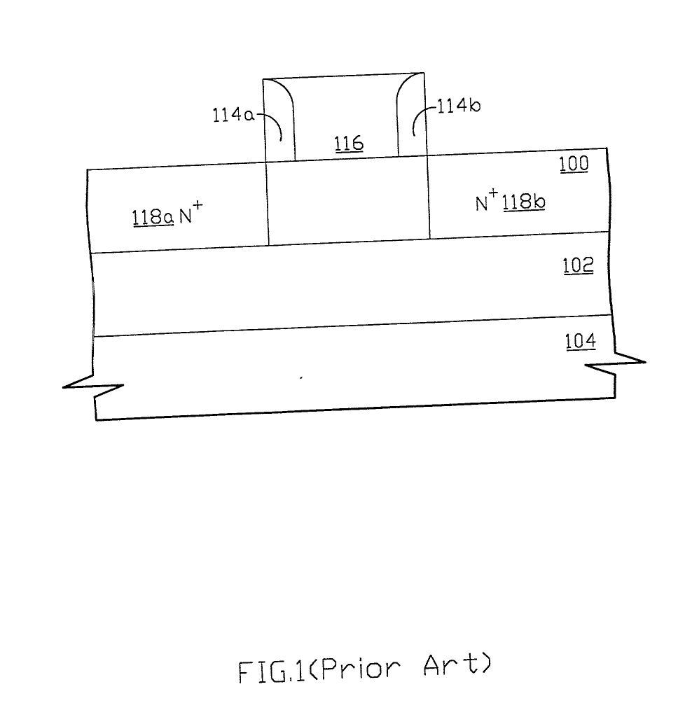

### DESCRIPTION OF THE PREFERRED EMBODIMENT

The invention uses a dielectric layer as a mask, a oxygen implantation and a heating process to form a silicon dioxide layer within a silicon-on-insulator substrate before forming a gate electrode on the silicon-on-insulator substrate. That is, the junction depth of the channel is reduced, meanwhile, without decreasing the junction depth of the source and drain regions. Furthermore, the invention increases the ability of channel control of the gate electrode without increasing the resistances of the source and drain regions and the RC time delay value of the SOI device. With good performance of channel control, the gate voltage of the SOI device of this invention can be decreased.

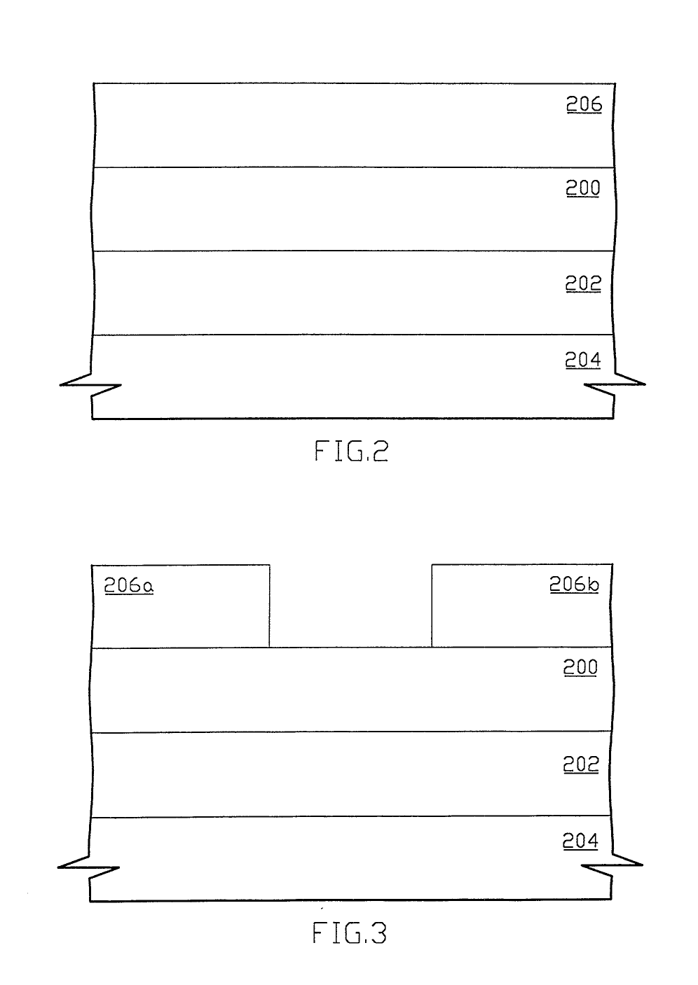

Referring to FIG. 2, a SOI substrate comprised a silicon layer 200, a silicon dioxide layer 202 and a silicon layer 204 is shown, wherein a first dielectric layer 206 is deposited on the silicon layer 200. The surface silicon layer 200 can be P-type and N-type silicon layers, and it is preferably a P-type layer with a <100>crystal orientation. The first dielectric layer 206 is preferably a silicon dioxide layer and it can be deposited by using a conventional chemical vapor deposition (CVD) process. For example, the CVD process can be a low pressure chemical vapor deposition (LPCVD) process with a deposition temperature of between about 400° C. to about 450° C. Moreover, the precursors of the LPCVD process are silane (SiH₄) and oxygen (O₂)

Referring to FIG. 3, a trench between dielectric layers 206a, 206b is formed by transferring a gate region pattern into the first dielectric layer 206 to expose the silicon layer 200. The trench can be formed by using conventional lithography and etching processes. The etching process is preferably a dry etching process, for example, a reactive ion etching process used carbon tetrafluoride (CF₄) plasma with a radio frequency of 13.56 MHz.

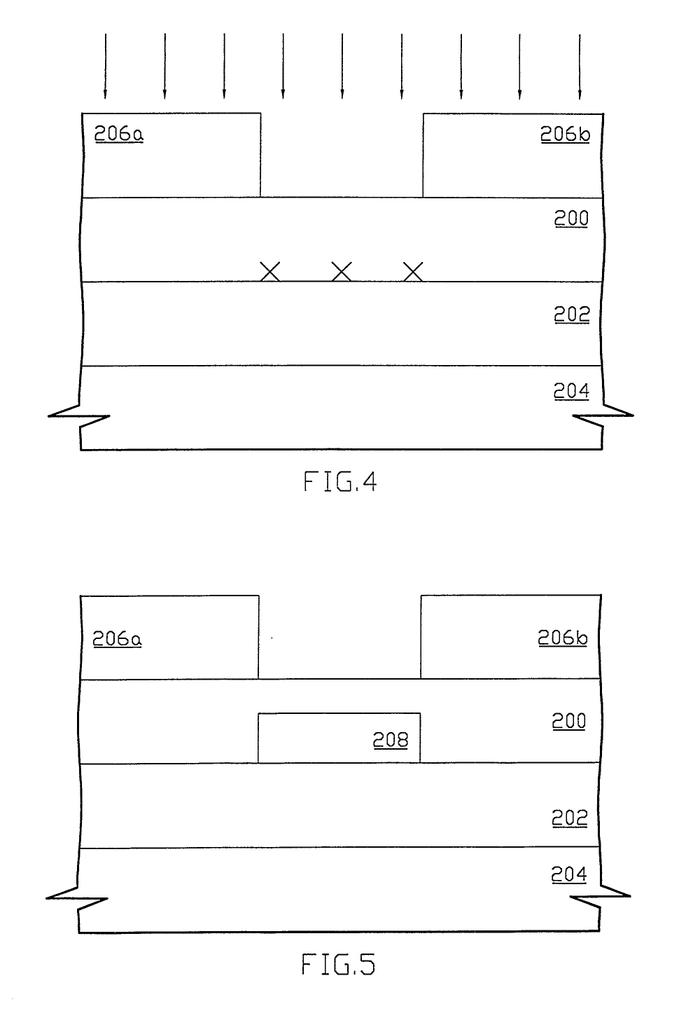

Referring to FIG. 4, an implantation process of oxygen (O₂) is performed on the SOI substrate shown in FIG. 3. Oxygen molecules are implanted into the silicon layer 200 and to a predetermined depth. The junction depth of the channel can be adjusted by changing the implant energy. And the implant energy, which can vary between about 20 keV to about 900 keV, depends on the implantation depth desired. That is, the less the implant energy, the shallower the oxygen are implanted, and the thinner the channel is. The dosage, which can vary between about 0.5×10¹⁷ to about 2×10¹⁸/cm², depends on the junction depth of the channel preferred.

Referring now to FIG. 5, a silicon dioxide layer 208 is formed within the silicon layer 200 by annealing the SOI substrate. The annealing process distributes the implanted oxygen among neighboring silicon atoms, meanwhile, repairs the implant damage of the silicon layer 200. To get better material quality, the SOI substrate is preferably annealed at a temperature of between about 800° C. to about 1200° C. Furthermore, the annealing process takes more than 6 hours. Moreover, the heating process can also be a rapid thermal processing (RTP) process performed at a temperature between about 650° C. to about 850° C. in argon (Ar) for low thermal budget and better throughput, moreover, it only takes about 30 to about 90 seconds.

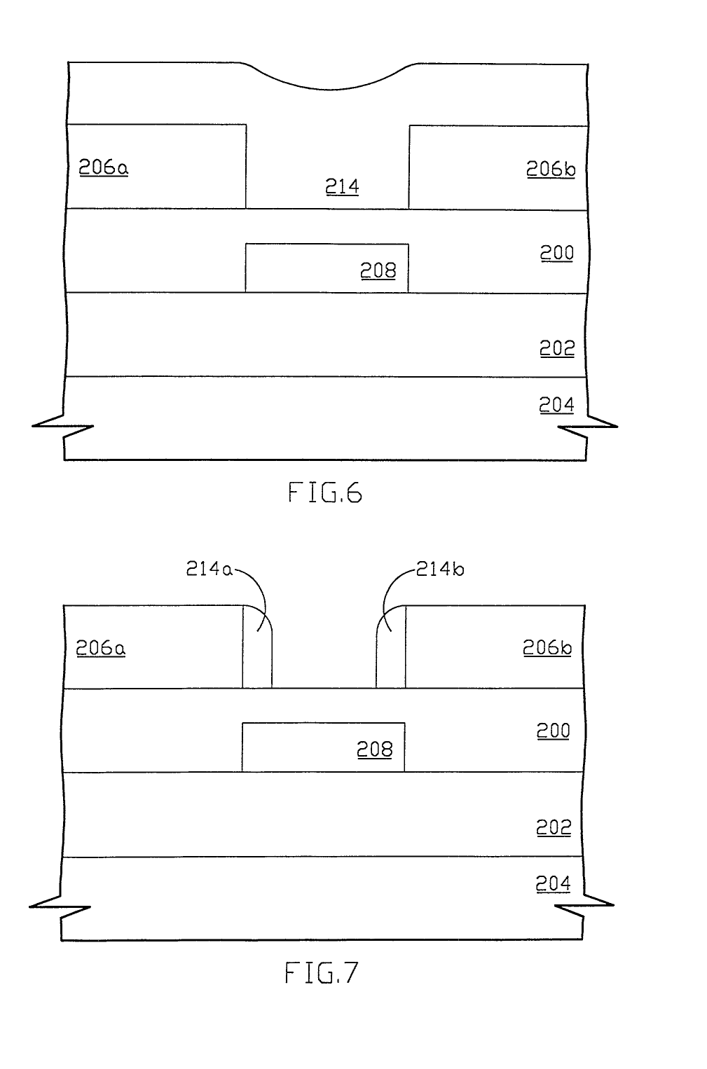

Referring now to FIG. 6, a second dielectric layer 214 is deposited overlying the dielectric layers 206a, 206b and the trench shown in FIG. 5 is filled with the same. The second dielectric layer 214 is preferably a silicon nitride layer deposited by using a conventional chemical vapor deposition process. The CVD process is preferably a LPCVD process whose precursors are dichlorosilane (SiH₂Cl₂) and ammonia (NH₃), which react at a temperature of between about 650° C. to about 800° C., and a pressure of between about 0.1 torr to about 1 torr.

Referring now to FIG. 7, two spacers 214a, 214b are formed in the trench by anisotropically etching the second dielectric layer 214. The second dielectric layer 214, which is preferably a silicon nitride layer, is preferably etched by using a reactive ion etching (RIE) process used a nitrogen fluoride (NF₃) plasma.

Referring now to FIG. 8, the trench shown in FIG. 7 is filled with a conductive layer to form a gate electrode 216. The conductive layer is preferably a polysilicon layer deposited by using a conventional LPCVD process. The precursors of the LPCVD process is silane (SiH₄) By heating at a temperature of between 600° C. to 650° C. and a pressure of between 0.3 torr to 0.6 torr, silane decompose to form polysilicon and hydrogen (H₂). Furthermore, the conductive layer can be planarized to expose the dielectric layer 206a, 206b and form the gate electrode 216 by using a conventional chemical mechanical polishing (CMP) process.

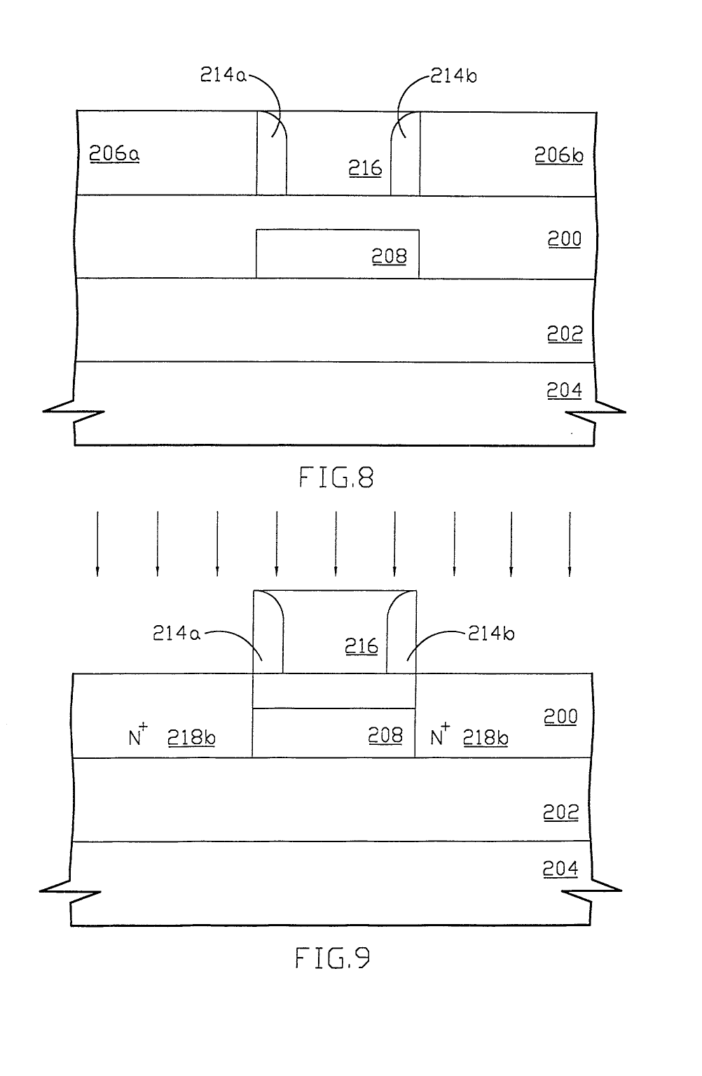

Referring now to FIG. 9, the dielectric layers 206a, 206b shown in FIG. 8 are removed by using a conventional etching method, for example, a wet etching process for silicon dioxide layers used a mixture of hydrofluoric acid (HF) and ammonium fluoride (NH₄F) solution. Moreover, an ion implantation process is performed on the silicon layer 200 to form source and drain regions 218a, 218b therein. The dopants can be phosphorus and arsenic ions implanted with an implant energy of between 20 keV to 80 keV for an NMOS device and a P-type substrate, and the dosage is 0.5×10¹⁴−1×10¹⁵/cm². Following the ion implantation, an annealing process used to drive-in the implanted ions and recover the implant damage, is sequentially performed at a temperature of between 800° C. to 1200° C.

Other embodiments of the invention will appear to those skilled in the art from consideration of the specification and practice of the invention disclosed herein. It is intended that the specification and examples to be considered as exemplary only, with a true scope and spirit of the invention being indicated by the following claims.

What is claim is:

1. A method for manufacturing a semiconductor device on a silicon-on-insulator substrate, said method comprising:
providing a silicon-on-insulator substrate having a silicon layer and an insulating layer, wherein said silicon layer is on said insulating layer;
depositing a first dielectric layer on said silicon layer;
transferring a gate region pattern into said first dielectric layer to form a trench and expose said silicon layer;
implanting oxygen into said silicon layer;
heating said silicon-on-insulator substrate to form a silicon dioxide layer in said silicon layer;
depositing a second dielectric layer overlying said first dielectric layer and filling said trench;
etching said second dielectric layer anisotropically to form a spacer in said trench;
filling said trench with a conductive layer;
removing said first dielectric layer; and
forming source and drain regions in said silicon layer.

2. The method according to claim 1, wherein said first dielectric layer is a silicon dioxide layer.

3. The method according to claim 1, wherein said first dielectric layer is deposited by using a low pressure chemical vapor deposition process.

4. The method according to claim 1, wherein said first dielectric layer is deposited by using a plasma enhanced chemical vapor deposition process.

5. The method according to claim 1, wherein said first dielectric layer is etched by using a dry etching process.

6. The method according to claim 1, wherein said silicon dioxide layer is formed by heating said silicon-on-insulator substrate at a temperature of between about 800° C. to about 1200° C.

7. The method according to claim 1, wherein said silicon dioxide layer is formed by using a rapid thermal processing process at a temperature between about 650° C. to about 850° C.

8. The method according to claim 1, wherein said second dielectric layer is a silicon nitride layer.

9. The method according to claim 1, wherein said second dielectric layer is deposited by using a low pressure chemical vapor deposition process.

10. The method according to claim 1, wherein said conductive layer is a polysilicon layer.

11. The method according to claim 1, wherein said conductive layer is etched by using a dry etching process.

12. The method according to claim 1, wherein said first dielectric layer is removed by using a wet etching process.

13. The method according to claim 1, wherein said first dielectric layer is removed by using a dry etching process.

14. A method for manufacturing a semiconductor device on a silicon-on-insulator substrate, said method comprising:
providing a silicon-on-insulator substrate having a silicon layer and an insulating layer, wherein said silicon layer is on said insulating layer;
depositing a first silicon dioxide layer on said silicon layer;
transferring a gate region pattern into said first silicon dioxide layer to form a trench and expose said silicon layer;
implanting oxygen into said silicon layer;
heating said silicon-on-insulator substrate to form a second silicon dioxide layer in said silicon layer;
depositing a dielectric layer overlying said first silicon dioxide layer and filling said trench;
etching said dielectric layer anisotropically to form a spacer in said trench;
filling said trench with a polysilicon layer by using a low pressure chemical vapor deposition process;
removing said first silicon dioxide layer; and
forming source and drain regions in said silicon layer.

15. The method according to claim 14, wherein said first silicon dioxide layer is deposited by using a low pressure chemical vapor deposition process.

16. The method according to claim 14, wherein said first silicon dioxide layer is deposited by using a plasma enhanced chemical vapor deposition process.

17. The method according to claim 14, wherein said first silicon dioxide layer is etched by using a dry etching process.

18. The method according to claim 14, wherein said second silicon dioxide layer is formed by heating said silicon-on-insulator substrate at a temperature of between about 800° C. to about 1200° C.

19. The method according to claim 14, wherein said second silicon dioxide layer is formed by using a rapid thermal processing process at a temperature between about 650° C. to about 850° C.

20. The method according to claim 14, wherein said dielectric layer is a silicon nitride layer.

21. The method according to claim 14, wherein said dielectric layer is deposited by using a low pressure chemical vapor deposition process.

22. The method according to claim 14, wherein said first silicon dioxide layer is removed by using a we t etching process.

23. The method according to claim 14, wherein said first dielectric layer is removed by using a dry etching process.

24. A method for manufacturing a semiconductor device on a silicon-on-insulator substrate, said method comprising:
providing a silicon-on-insulator substrate having a silicon layer and an insulating layer, wherein said silicon layer is on said insulating layer;
depositing a first silicon dioxide layer on said silicon layer by using a low pressure chemical vapor deposition process;
transferring a gate region pattern into said first silicon dioxide layer to form a trench and expose said silicon layer by using a dry etching process;
implanting oxygen into said silicon layer;
heating said silicon-on-insulator substrate to form a second silicon dioxide layer in said silicon layer;
depositing a silicon nitride layer overlying said first silicon dioxide layer and filling said trench by using a low pressure chemical vapor deposition process;
etching said dielectric layer anisotropically to form a spacer in said trench;
filling said trench with a polysilicon layer by using a low pressure chemical vapor deposition process;
removing said first silicon dioxide layer by using a wet etching process; and
forming source and drain regions in said silicon layer.

25. The method according to claim 24, wherein said second silicon dioxide layer is formed by heating said silicon-on-insulator substrate at a temperature of between about 800° C. to about 1200° C.

26. The method according to claim 24, wherein said second silicon dioxide layer is formed by using a rapid thermal processing process at a temperature between about 650° C. to about 850° C.
